(19) United States
(12) Patent Application Publication
(10) Pub. No.: US 2021/0296227 A1
(43) Pub. Date: Sep. 23, 2021

(54) SEMICONDUCTOR MEMORY DEVICE

(71) Applicant: Kioxia Corporation, Tokyo (JP)

(72) Inventor: Kenji WATANABE, Yokkaichi (JP)

(73) Assignee: Kioxia Corporation, Tokyo (JP)

(21) Appl. No.: 17/019,886

(22) Filed: Sep. 14, 2020

(30) Foreign Application Priority Data
Mar. 17, 2020 (JP) 2020-046658

(51) Int. Cl. H01L 23/528; H01L 23/522; H01L 27/11565; H01L 27/11582

(52) U.S. Cl. CPC H01L 23/528; H01L 23/5226; H01L 27/11573; H01L 27/11582; H01L 27/11565

(57) ABSTRACT

According to one embodiment, a semiconductor memory device includes a stacked layer body including first and second stacked portions having stair-like first and second ends, an insulating region including first and second insulating region portions covering the first and second ends of the stacked layer body, and a first contact wiring including first and second wiring portions extending in a first direction within the first and second insulating region portions and a third wiring portion connected between the first and second wiring portions. A pattern of the first wiring portion and a pattern of the second wiring portion are arranged at positions different from each other when viewed in the first direction.

### CROSS-REFERENCE TO RELATED APPLICATIONS

This application is based upon and claims the benefit of priority from Japanese Patent Application No. 2020-046658, filed Mar. 17, 2020, the entire contents of which are incorporated herein by reference.

### FIELD

Embodiments described herein relate generally to a semiconductor memory device.

### BACKGROUND

In three-dimensional type nonvolatile memory including a plurality of memory cells stacked in a vertical direction, it is difficult to properly form wirings with an increase in the number of stacked layers.

### BRIEF DESCRIPTION OF THE DRAWINGS

FIG. 1 is a diagram schematically illustrating an overall arrangement configuration of a semiconductor memory device according to an embodiment.

FIG. 2A is a cross-sectional view schematically illustrating a specific configuration of a memory region of a semiconductor memory device according to an embodiment.

FIG. 2B is a cross-sectional view schematically illustrating a specific configuration of a stairs region of a semiconductor memory device according to an embodiment.

FIG. 2C is a cross-sectional view schematically illustrating a specific configuration of a peripheral circuit region of a semiconductor memory device according to an embodiment.

FIG. 3 is a plan view schematically illustrating an example of an arrangement of pillar structures included in a memory region of a semiconductor memory device according to an embodiment.

FIG. 4A is a cross-sectional view schematically illustrating a detailed configuration of a memory cell section of a semiconductor memory device according to an embodiment.

FIG. 4B is a cross-sectional view schematically illustrating a detailed configuration of a memory cell section of a semiconductor memory device according to an embodiment.

FIG. 5 is a plan view (planar pattern view) schematically illustrating an example of a configuration of a contact wiring in a semiconductor memory device according to an embodiment.

### DETAILED DESCRIPTION

In general, according to one embodiment, a semiconductor memory device includes: a stacked layer body including a first stacked portion including a plurality of first conductive layers and a plurality of first insulating layers which are alternately stacked in a first direction and having a stair-like first end, and including a second stacked portion provided on an upper layer side of the first stacked portion, including a plurality of second conductive layers and a plurality of second insulating layers which are alternately stacked in the first direction and having a stair-like second end; a plurality of pillar structures each of which extending in the first direction within the stacked layer body and each of which including a semiconductor layer extending in the first direction and a charge storage layer surrounding a side surface of the semiconductor layer; an insulating region adjacent to the first and second ends of the stacked layer body, the insulating region including a first insulating region portion covering the first end of the stacked layer body and including a second insulating region portion provided on an upper layer side of the first insulating region portion and covering the second end of the stacked layer body; and a plurality of first contact wirings each of which including a first wiring portion that is connected to a portion located at the first end of the corresponding first conductive layer and extends in the first direction within the first insulating region portion, a second wiring portion extending in the first direction within the second insulating region portion, and a third wiring portion connected between an upper end of the first wiring portion and a lower end of the second wiring portion, wherein a pattern of the first wiring portion and a pattern of the second wiring portion included in one of the first contact wirings are arranged at positions different from each other when viewed in the first direction.

Hereinafter, embodiments will be described with reference to the drawings.

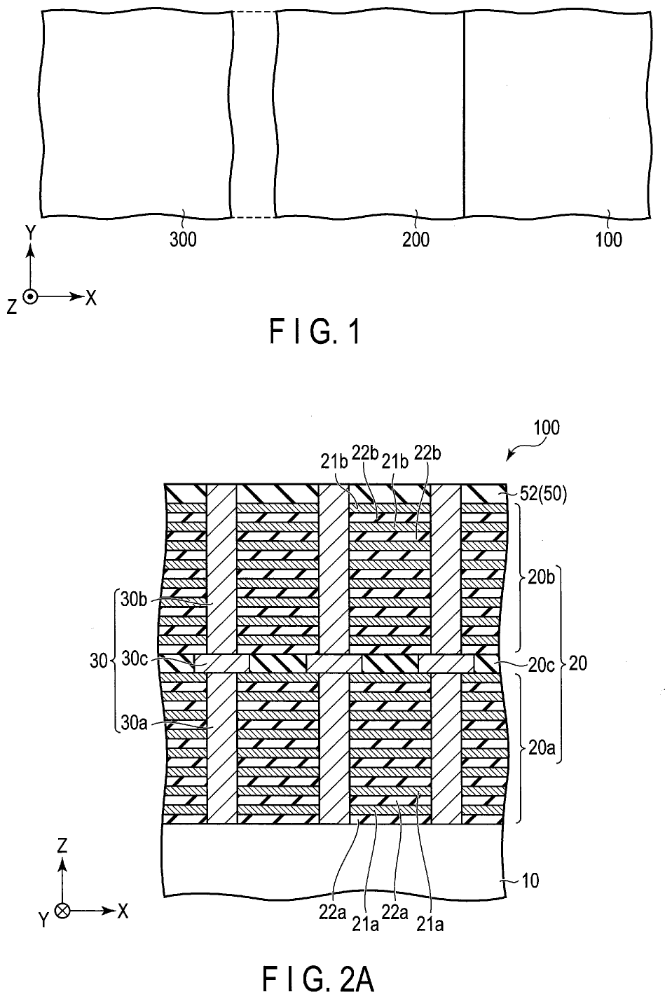

FIG. 1 is a diagram schematically illustrating an overall arrangement configuration of a semiconductor memory device according to the present embodiment. The X direction, the Y direction, and the Z-direction illustrated in FIG. 1 and drawings subsequent to FIG. 1 are directions perpendicular to each other.

As illustrated in FIG. 1, the semiconductor memory device according to the present embodiment includes a memory region 100, a stairs region 200, and a peripheral circuit region 300. The memory region 100, the stairs region 200, and the peripheral circuit region 300 are arranged on a same semiconductor substrate.

The memory region 100 includes a NAND nonvolatile memory cell array having a three-dimensional structure. Specifically, a plurality of memory cells arranged in a direction perpendicular to the main surface of the semiconductor substrate (Z-direction, first direction) forms a NAND string. A plurality of the NAND strings is arrayed parallel to the main surface of the semiconductor substrate.

The stairs region 200 is arranged adjacent to the memory region 100, and includes a terminal for contact with a word line as described below.

The peripheral circuit region 300 includes peripheral circuits for the memory cell array provided in the memory region 100.

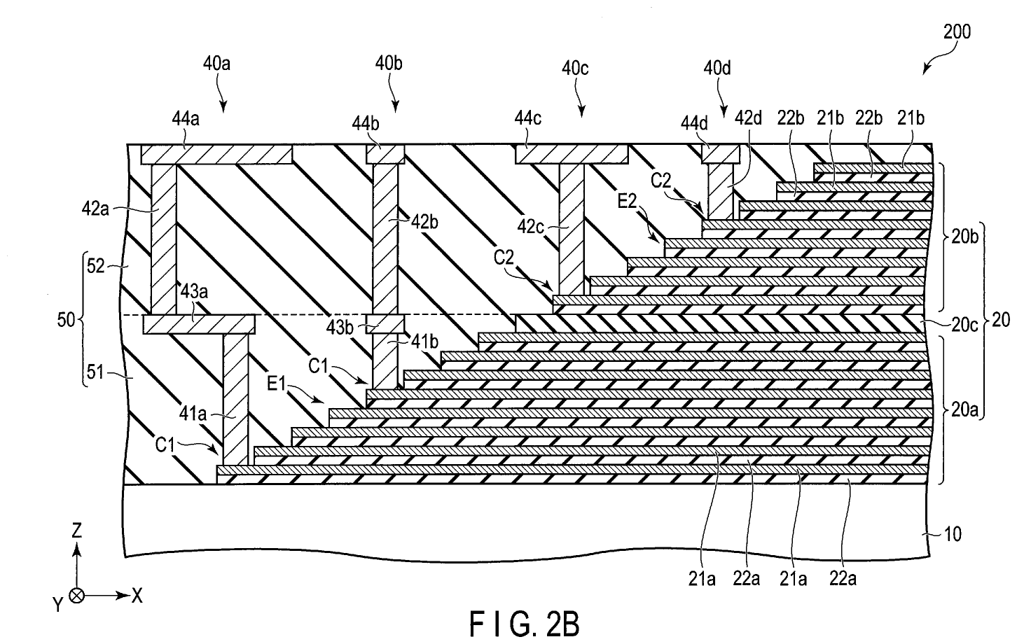

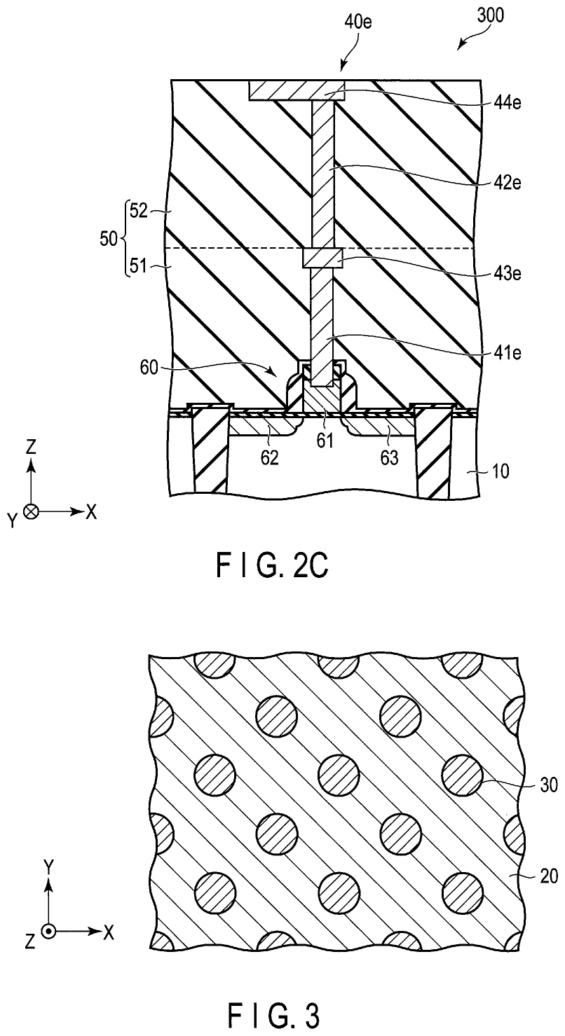

FIGS. 2A, 2B, and 2C are cross-sectional views schematically illustrating specific configurations of the memory region 100, the stairs region 200, and the peripheral circuit region 300, respectively.

In the memory region 100 and the stairs region 200, a stacked layer body 20 is provided on the semiconductor substrate 10. The stacked layer body 20 is continuously provided across the memory region 100 and the stairs region 200.

The stacked layer body 20 includes: a stacked portion (first stacked portion) 20a in which a plurality of conductive layers (first conductive layers) 21a and a plurality of insulating layers (first insulating layers) 22a are alternately stacked in a direction (Z-direction, first direction) perpendicular to the main surface of the semiconductor substrate 10 and having a stair-like end (first end) E1; a stacked portion (second stacked portion) 20b provided on an upper layer side of the stacked portion 20a and in which a plurality of conductive layers (second conductive layers) 21b and a plurality of insulating layers (second insulating layers) 22b are alternately stacked in the Z-direction and having a stair-like end (second end) E2; and an intermediate portion 20c located between the stacked portion 20a and the stacked portion 20b. In this specification, the facing direction of a terrace surface of the stairs is defined as an upward direction at the stair-like ends E1 and E2 of the stacked layer body 20. In the following description, the conductive layers 21a and 21b are referred to as the conductive layers 21 and the insulating layers 22a and 22b are referred to as the insulating layers 22 in some cases for convenience.

The conductive layer 21 functions as a word line, and the insulating layer 22 insulates the conductive layers 21 from each other. The conductive layer 21 is formed of a metal material such as tungsten (W), while the insulating layer 22 is formed of an insulating material such as silicon oxide. The intermediate portion (intermediate layer) 20c is formed of an insulating material such as silicon oxide.

The stacked layer body 20 is adjacent to a region including an insulating region 50. The insulating region 50 includes a first insulating region portion 51 that is adjacent to the stair-like end E1 of the stacked layer body 20 and covers the stair-like end E1 of the stacked layer body 20. A second insulating region portion 52 of the insulating region 50, provided on an upper layer side of the first insulating region portion 51, is adjacent to the stair-like end E2 of the stacked layer body 20, and covers the stair-like end E2 of the stacked layer body 20. The insulating region 50 is formed of an insulating material such as silicon oxide.

The memory region 100 includes a plurality of pillar structures 30 each of which extending in the Z-direction (first direction) within the stacked layer body 20. As described below, each of the pillar structures 30 includes: a semiconductor layer extending in the Z-direction; and a charge storage layer surrounding a side surface of the semiconductor layer.

FIG. 3 is a plan view schematically illustrating an example of an arrangement of the pillar structures 30 included in the memory region 100. As illustrated in FIG. 3, the plurality of pillar structures 30 are arranged in parallel to an X-Y plane (plane perpendicular to the Z-direction), and each of the pillar structures 30 is surrounded by the stacked layer body 20.

As illustrated in FIG. 2A, each of the pillar structures 30 includes: a pillar portion (first pillar portion) 30a extending in the Z-direction within the stacked portion 20a of the stacked layer body 20; a pillar portion (second pillar portion) 30b located above the pillar portion 30a and extending in the Z-direction within the stacked portion 20b of the stacked layer body 20; and an intermediate portion 30c located between the pillar portion 30a and the pillar portion 30b. Accordingly, the pillar portion 30a is surrounded by the stacked portion 20a of the stacked layer body 20, the pillar portion 30b is surrounded by the stacked portion 20b of the stacked layer body 20, and the intermediate portion 30c is surrounded by the intermediate portion 20c of the stacked layer body 20. The pillar portion 30a and the pillar portion 30b function as portions that form a memory cell, while the intermediate portion 30c functions as a joint that connects the pillar portion 30a and the pillar portion 30b. When viewed in the Z-direction, an area of a pattern of the intermediate portion 30c is larger than an area of a pattern of the pillar portion 30a and an area of a pattern of the pillar portion 30b.

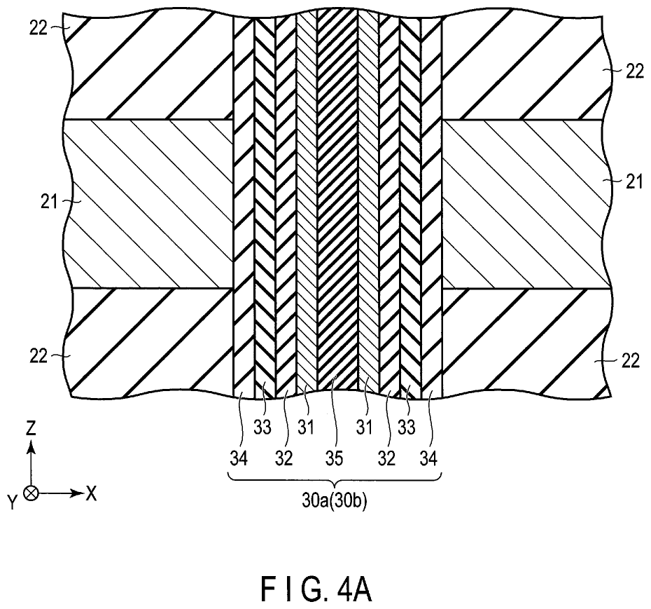

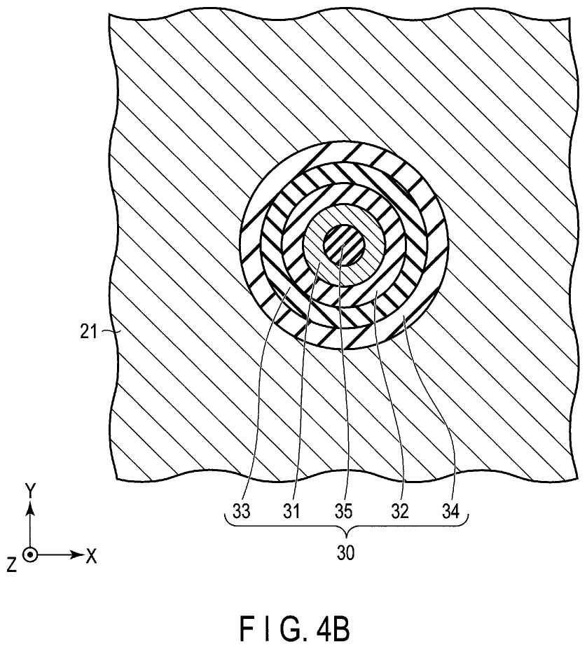

FIGS. 4A and 4B are cross-sectional views each schematically illustrating a detailed configuration of a memory cell section formed by the conductive layer 21 of the stacked layer body 20 and the pillar portions (pillar portion 30a and pillar portion 30b) of the pillar structure 30. FIG. 4A is a cross-sectional view in a direction parallel to the Z-direction. FIG. 4B is a cross-sectional view in a direction perpendicular to the Z-direction.

Each of portions of the pillar structure 30, namely, the pillar portion 30a and the pillar portion 30b, includes a semiconductor layer 31, a tunnel insulating layer 32, a charge storage layer 33, a block insulating layer 34, and a core insulating layer 35. The semiconductor layer 31, the tunnel insulating layer 32, the charge storage layer 33, and the block insulating layer 34 have cylindrical shapes, while the core insulating layer 35 has a columnar shape. Specifically, the semiconductor layer 31 surrounds a side surface of the core insulating layer 35, the tunnel insulating layer 32 surrounds a side surface of the semiconductor layer 31, the charge storage layer 33 surrounds a side surface of the tunnel insulating layer 32, and the block insulating layer 34 surrounds a side surface of the charge storage layer 33. The semiconductor layer 31 is formed of silicon, the tunnel insulating layer 32 is formed of silicon oxide, the charge storage layer 33 is formed of silicon nitride, the block insulating layer 34 is formed of silicon oxide, and the core insulating layer 35 is formed of silicon oxide.

Incidentally, the basic structure of the intermediate portion 30c of the pillar structure 30 is similar to that of the pillar portion 30a and the pillar portion 30b of the pillar structure 30, and thus, the intermediate portion 30c includes the semiconductor layer 31, the tunnel insulating layer 32, the charge storage layer 33, the block insulating layer 34, and the core insulating layer 35.

The conductive layer 21 surrounding the pillar portions of the pillar structure 30 (the pillar portion 30a and the pillar portion 30b) functions as a gate electrode. The portion functioning as the gate electrode of the conductive layer 21 and the portion surrounded by the conductive layer 21 of the pillar portion constitute a memory cell.

In the stairs region 200 illustrated in FIG. 2B, as described above, the stacked portion 20a and the stacked portion 20b of the stacked layer body 20 have the stair-like ends E1 and E2, respectively. Specifically, a step is formed for each of pairs of the conductive layer 21 and the insulating layer 22. That is, a step is provided for each of word lines formed of the conductive layer 21.

The ends E1 and E2 of the stacked layer body 20 are connected to a plurality of contact wirings 40a, 40b, 40c, and 40d functioning as contacts to the word lines. The contact wirings 40a, 40b, 40c, and 40d are formed of a metal material such as tungsten (W). In FIG. 2B, each of the contact wirings 40a, 40b, 40c, and 40d is illustrated as a single element, for convenience. However, each of the contact wirings 40a, 40b, 40c, and 40d may be provided in plurality.

The contact wirings (first contact wirings) 40a and 40b are connected to the conductive layer 21 provided in the stacked portion 20a of the stacked layer body 20. These contact wirings 40a and 40b are formed in a same manufacturing process. The contact wirings 40a and 40b include wiring portions (first wiring portions) 41a and 41b, wiring portions (second wiring portions) 42a and 42b, wiring portions (third wiring portions) 43a and 43b, and wiring portions (fourth wiring portions) 44a and 44b, respectively.

Each of the wiring portions 41a and 41b is connected to a portion (connection portion C1) located at the stair-like end E1 of the corresponding conductive layer 21a so as to extend in the Z-direction within the insulating region portion 51. Each of the wiring portions 41a and 41b has a pillar-like shape, and the positions of the upper surfaces of the wiring portions 41a and 41b in the height direction correspond to the positions of the upper surface of the stacked portion 20a in the height direction.

The wiring portions 42a and 42b are located on the upper layer side of the wiring portions 41a and 41b, respectively, and extend in the Z-direction within the insulating region portion 52. Each of the wiring portions 42a and 42b has a pillar-like shape, and the positions of the upper surfaces of the wiring portions 42a and 42b in the height direction correspond to the positions of the upper surface of the stacked portion 20b in the height direction.

The wiring portion 43a is connected between the wiring portion 41a and the wiring portion 42a; the wiring portion 43b is connected between the wiring portion 41b and the wiring portion 42b. The positions of the wiring portions 43a and 43b in the height direction correspond to the positions of the intermediate portion 20c of the stacked layer body 20 in the height direction. Therefore, the position of the lower surface of the wiring portions 43a and 43b in the height direction corresponds to the position of the upper surface of the stacked portion 20a in the height direction; the position of the upper surface of the wiring portions 43a and 43b in the height direction corresponds to the position of the lower surface of the stacked portion 20b in the height direction. The positions of the wiring portions 43a and 43b in the height direction correspond to the position of the intermediate portion 30c of the pillar structure 30 in the height direction.

The wiring portion 43a is connected between the upper end of the wiring portion 41a and the lower end of the wiring portion 42a, and includes an extension portion that extends parallel to a plane (X-Y plane) perpendicular to the Z-direction between the upper end of the wiring portion 41a and the lower end of the wiring portion 42a. Therefore, when viewed in the Z-direction, the pattern of the wiring portion 41a and the pattern of the wiring portion 42a are arranged at different positions from each other, that is, not overlapping each other. The wiring portion 43a may run linearly or may be bent at one or more positions. In other words, the wiring portion 43a may extend only in one direction, or may extend in a plurality of directions.

The wiring portion 43b is also connected between the upper end of the wiring portion 41b and the lower end of the wiring portion 42b. When viewed in the Z-direction, the pattern of the wiring portion 41b, the pattern of the wiring portion 42b, and the pattern of the wiring portion 43b are arranged at positions corresponding to each other. Accordingly, the wiring portion 43b does not include an extension portion, unlike the wiring portion 43a.

The wiring portion 44a is connected to the upper end of the wiring portion 42a; the wiring portion 44b is connected to the upper end of the wiring portion 42b. The wiring portion 44a may include or need not include an extension portion extending from the portion connected to the upper end of the wiring portion 42a in parallel to the X-Y plane. Similarly, the wiring portion 44b may include such an extension portion or need not include such an extension portion.

The contact wirings (second contact wirings) 40c and 40d are connected to the conductive layer 21b provided in the stacked portion 20b of the stacked layer body 20. The contact wirings 40c and 40d are formed in a same manufacturing process. More specifically, the contact wirings 40c and 40d are formed in the same manufacturing process as the upper layer side portions (wiring portions 42a and 42b, and wiring portions 44a and 44b) of the contact wirings (first contact wirings) 40a and 40b. The contact wirings 40c and 40d include wiring portions (fifth wiring portions) 42c and 42d and wiring portions (sixth wiring portions) 44c and 44d, respectively.

Each of the wiring portions 42c and 42d is connected to a portion (connection portion C2) located at the stair-like end E2 of the corresponding conductive layer 21b so as to extend in the Z-direction within the insulating region portion 52. Each of the wiring portions 42c and 42d has a pillar-like shape, and the positions of the upper surfaces of the wiring portions 42c and 42d in the height direction correspond to the positions of the upper surface of the stacked portion 20b in the height direction. In other words, the positions of the upper surfaces of the wiring portions 42c and 42d in the height direction correspond to the positions of the upper surfaces of the wiring portions 42a and 42b in the height direction, respectively.

The wiring portion 44c is connected to the upper end of the wiring portion 42c. The wiring portion 44d is connected to the upper end of the wiring portion 42d. The wiring portion 44c may include or need not include an extension portion extending from the portion connected to the upper end of the wiring portion 42c in parallel to the X-Y plane. Similarly, the wiring portion 44d may include or need not include such an extension portion.

As illustrated in FIG. 2C, the peripheral circuit region 300 includes a MOS transistor 60 and a contact wiring (third contact wiring) 40e connected to the MOS transistor 60. Note that although FIG. 2C illustrates one MOS transistor 60 and one contact wiring 40e for convenience, there are provided, in practice, a plurality of MOS transistors 60 and a plurality of contact wirings 40e in the peripheral circuit region 300. Furthermore, although the contact wiring 40e is connected to a gate electrode 61 of the MOS transistor 60 in FIG. 2C, a contact wiring may also be connected to a source 62 and a drain 63.

The contact wiring 40e includes a wiring portion (seventh wiring portion) 41e, a wiring portion (eighth wiring portion) 42e, a wiring portion (ninth wiring portion) 43e, and a wiring portion (tenth wiring portion) 44e, and is formed in the same manufacturing process as the contact wirings (first contact wirings) 40a and 40b in the stairs region 200.

The wiring portion 41e is connected to the MOS transistor 60 and extends in the Z-direction in the insulating region portion 51. The wiring portion 41e has a pillar-like shape, and the position of the upper surface of the wiring portion 41e in the height direction corresponds to the positions of the upper surface of the wiring portions 41a and 41b of the contact wirings 40a and 40b in the height direction (that is, the position of the upper surface of the stacked portion 20a in the height direction).

The wiring portion 42e is located on the upper layer side of the wiring portion 41e, and extends in the Z-direction in the insulating region portion 52. The wiring portion 42e has a pillar-like shape, and the position of the upper surface of the wiring portion 42e in the height direction corresponds to the positions of the upper surface of the wiring portions 42a and 42b of the contact wirings 40a and 40b in the height direction (that is, the position of the upper surface of the stacked portion 20b in the height direction).

The wiring portion 43e is connected between the upper end of the wiring portion 41e and the lower end of the wiring portion 42e. The position of the wiring portion 43e in the height direction corresponds to the position of the wiring portions 43a and 43b of the contact wirings 40a and 40b in the height direction (that is, the position of the intermediate portion 20c of the stacked layer body 20 in the height direction). Accordingly, the position of the lower surface of the wiring portion 43e in the height direction corresponds to the position of the lower surface of the wiring portions 43a and 43b in the height direction (that is, the position of the upper surface of the stacked portion 20a in the height direction). The position of the upper surface of the wiring portion 43e in the height direction corresponds to the position of the upper surface of the wiring portions 43a and 43b in the height direction (that is, the position of the lower surface of the stacked portion 20b in the height direction). The wiring portion 43e may include or need not include an extension portion extending between the upper end of the wiring portion 41e and the lower end of the wiring portion 42e in parallel to the X-Y plane.

The wiring portion 44e is connected to the upper end of the wiring portion 42e. The wiring portion 44e may include or need not include an extension portion extending from the portion connected to the upper end of the wiring portion 42e in parallel to the X-Y plane.

The above-described structures of FIGS. 2A, 2B, and 2C are manufactured by a roughly two-step process.

In the first step, the lower portions of the memory region 100, the stairs region 200, and the peripheral circuit region 300 are formed. Specifically, there will be formed, on the semiconductor substrate 10, the stacked portion 20a and the intermediate portion 20c of the stacked layer body 20, the pillar portion 30a and the intermediate portion 30c of the pillar structure 30, the wiring portions 41a and 43a of the contact wiring 40a, the wiring portions 41b and 43b of the contact wiring 40b, the wiring portions 41e and 43e of the contact wiring 40e, the insulating region portion 51 of the insulating region 50, and the MOS transistor 60.

The stacked portion 20a and the intermediate portion 20c of the stacked layer body 20 are formed by performing stair-like patterning of the plurality of conductive layers 21a and the plurality of insulating layers 22a which are alternately stacked, and the insulating layer for the intermediate portion 20c. Furthermore, the pillar portion 30a and the intermediate portion 30c of the pillar structure 30 are formed in holes formed in the stacked portion 20a and the intermediate portion 20c of the stacked layer body 20.

The wiring portions 41a, 43a, 41b, 43b, 41e, and 43e are formed in a common process. Specifically, there will be formed, in the insulating region portion 51, holes for the wiring portions 41a, 41b, and 41e in a common step, and trenches for the wiring portions 43a, 43b, and 43e in a common step. Thereafter, the holes for the wiring portions 41a, 41b, and 41e and the trenches for the wiring portions 43a, 43b, and 43e are filled in a common process with a metal material such as tungsten (W), leading to formation of the wiring portions 41a, 43a, 41b, 43b, 41e, and 43e.

In the second step, the upper portions of the memory region 100, the stairs region 200, and the peripheral circuit region 300 are formed. Specifically, on the structure obtained in the first step, there will be formed the stacked portion 20b of the stacked layer body 20, the pillar portion 30b of the pillar structure 30, the wiring portions 42a and 44a of the contact wiring 40a, the wiring portions 42b and 44b of the contact wiring 40b, the wiring portions 42c and 44c of the contact wiring 40c, the wiring portions 42d and 44d of the contact wiring 40d, the wiring portions 42e and 44e of the contact wiring 40e, and the insulating region portion 52 of the insulating region 50.

The stacked portion 20b of the stacked layer body 20 is formed by performing stair-like patterning of the plurality of conductive layers 21b and the plurality of insulating layers 22b which are alternately stacked. Furthermore, the pillar portion 30b of the pillar structure 30 is formed in the hole formed in the stacked portion 20b of the stacked layer body 20.

The wiring portions 42a, 44a, 42b, 44b, 42c, 44c, 42d, 44d, 42e, and 44e are formed in a common process. Specifically, there will be formed, in the insulating region portion 52, holes for the wiring portions 42a, 42b, 42c, 42d, and 42e in a common process, and trenches for the wiring portions 44a, 44b, 44c, 44d, and 44e in a common process. Thereafter, the holes for the wiring portions 42a, 42b, 42c, 42d, and 42e and the trenches for the wiring portions 44a, 44b, 44c, 44d, and 44e are filled in a common process with a metal material such as tungsten (W), leading to formation of the wiring portions 42a, 44a, 42b, 44b, 42c, 44c, 42d, 44d, 42e, and 44e.

In the following description, for simplification, the contact wirings 40a, 40b, 40c, 40d, and 40e are referred to as a contact wiring 40, the wiring portions 41a, 41b, and 41e are referred to as a wiring portion 41, the wiring portions 42a, 42b, 42c, 42d, and 42e are referred to as a wiring portion 42, the wiring portions 43a, 43b, and 43e are referred to as a wiring portion 43, and wiring portions 44a, 44b, 44c, 44d, and 44e are referred to as a wiring portion 44, in some cases.

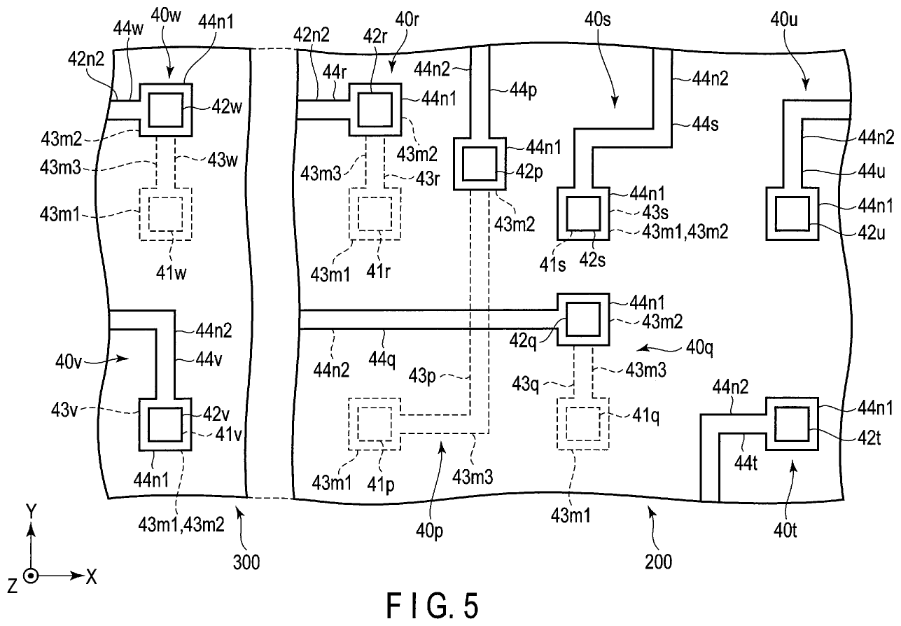

FIG. 5 is a plan view (planar pattern view) schematically illustrating an example of a configuration of a contact wiring in the semiconductor memory device according to the present embodiment.

FIG. 5 illustrates six contact wirings 40p, 40q, 40r, 40s, 40t, and 40u included in the stairs region 200. Of these six contact wirings, the four contact wirings (first contact wirings) 40p, 40q, 40r, and 40s on the left are connected to the conductive layer 21a located in the stacked portion 20a, while the two contact wirings (second contact wirings) 40t and 40u on the right are connected to the conductive layer 21b located in the stacked portion 20b. Furthermore, the peripheral circuit region 300 includes two contact wirings (third contact wirings) 40v and 40w.

The broken lines indicate first wiring portions (41p, 41q, 41r, and 41s), third wiring portions (43p, 43q, 43r, and 43s), seventh wiring portions (41v and 41w) and ninth wiring portions (43v and 43w). The solid lines indicate second wiring portions (42p, 42q, 42r, and 42s), fourth wiring portions (44p, 44q, 44r, and 44s), fifth wiring portions (42t and 42u), sixth wiring portions (44t and 44u), eighth wiring portions (42v and 42w) and tenth wiring portions (44v and 44w).

In the following description, for simplification, the contact wirings 40p, 40q, 40r, 40s, 40t, 40u, 40v, and 40w are referred to as the contact wiring 40, the wiring portions 41p, 41q, 41r, 41s, 41v, and 41w are referred to as the wiring portion 41, the wiring portion 42p, 42q, 42r, 42s, 42t, 42u, 42v, and 42w are referred to as the wiring portion 42, the wiring portions 43p, 43q, 43r, 43s, 43v, and 43w are referred to as the wiring portion 43, and the wiring portions 44p, 44q, 44r, 44s, 44t, 44u, 44v, and 44w are referred to as the wiring portion 44, in some cases.

In the contact wirings 40p, 40q, 40r, and 40w in the example illustrated in FIG. 5, the pattern of the wiring portion 41 (41p, 41q, 41r, and 41w) and the pattern of the wiring portion 42 (42p, 42q, 42r, and 42w) are arranged at positions different from each other when viewed in the Z-direction. In the contact wirings 40s and 40v, the pattern of the wiring portion 41 (41s and 41v) and the pattern of the wiring portion 42 (42s and 42v) are arranged at positions corresponding to each other when viewed in the Z-direction.

Of the wiring portion 43, the wiring portions 43p, 43q, 43r, and 43w include: an end portion 43m1 including a portion connected to the wiring portion 41; an end portion 43m2 including a portion connected to the wiring portion 42; and an extension portion 43m3 extending between the end portion 43m1 and the end portion 43m2, in parallel with the X-Y plane. The extension portion 43m3 may run linearly like the wiring portions 43q, 43r, and 43w, or may be bent at one or more position like the wiring portion 43p. Furthermore, in the wiring portions 43s and 43v, the end portions 43m1 and 43m2 are arranged as positions corresponding to each other.

When viewed in the Z-direction, the pattern width of the end portion 43m1 and the end portion 43m2 is wider than the pattern width of the extension portion 43m3. Furthermore, when viewed in the Z-direction, the pattern of the end portion 43m1 includes the pattern of the wiring portion 41 and thus has a larger area than the pattern of the wiring portion 41. This configuration makes it possible to reliably ensure the connection between the wiring portion 41 and the end portion 43m1 of the wiring portion 43. Furthermore, when viewed in the Z-direction, the pattern of the end portion 43m2 includes the pattern of the wiring portion 42 and thus has a larger area than the pattern of the wiring portion 42. This configuration makes it possible to reliably ensure the connection between the wiring portion 42 and the end portion 43m2 of the wiring portion 43.

The wiring portion 44 includes: an end portion 44n1 including a portion connected to the wiring portion 42; and an extension portion 44n2 extending from the end portion 44n1 in parallel with the X-Y plane.

When viewed in the Z-direction, the pattern width of the end portion 44n1 is wider than the pattern width of the extension portion 44n2. Furthermore, when viewed in the Z-direction, the pattern of the end portion 44n1 includes the pattern of the wiring portion 42 and thus has a larger area than the pattern of the wiring portion 42.

As described above, the stairs region 200 in the present embodiment includes the third wiring portion (the wiring portion 43a in FIG. 2B, the wiring portions 43p, 43q, and 43r in FIG. 5) extending parallel to the X-Y plane, enabling proper arrangement of the contact wiring 40 connected to the stair-like end E1 of the conductive layer 21a.

In a case where all the first contact wirings 40 provided in the stairs region 200 are provided with no extension portion to the third wiring portion 43, and where the first wiring portion 41, the second wiring portion 42, and the third wiring portion 43 are linearly extended in the vertical direction (Z-direction) (in other words, where the pattern of the first wiring portion 41, the pattern of the second wiring portion 42, and the pattern of the third wiring portion 43 are arranged at a same position when viewed in the Z-direction), the connection position between the second wiring portion 42 and the fourth wiring portion 44 would be at the same position as the connection position between the first wiring portion 41 and the conductive layer 21, when viewed in the Z-direction. That is, the connection position between the second wiring portion 42 and the fourth wiring portion 44 would be uniquely determined depending on the connection position between the first wiring portion 41 and the conductive layer 21. This would result in occurrence of positions having a reduced space between the fourth wiring portions 44, leading to a risk of occurrence of short-circuit defects between the fourth wiring portions 44.

In the present embodiment, the contact wirings (40a, 40p, 40q, and 40r) are provided to have the third wiring portions (43a, 43p, 43q, and 43r) extending parallel to the X-Y plane. In other words, these contact wirings (40a, 40p, 40q, and 40r) have a configuration in which the pattern of the first wiring portion (41a, 41p, 41q, and 41r) and the pattern of the second wiring portion (42a, 42p, 41q, and 41r) are arranged at different positions from each other without overlapping each other when viewed in the Z-direction. This configuration achieves a large degree of freedom for the connection position of the second wiring portion 42 and the fourth wiring portion 44.

For example, in the contact wiring 40p of FIG. 5, the third wiring portion 43p is provided across the fourth wiring portion 44q of the contact wiring 40q. This allows the second wiring portion 42p to be apart from the first wiring portion 41p, and in addition, the fourth wiring portion 44p is connected to the second wiring portion 42p provided at such a position.

Therefore, in the present embodiment, it is possible to suppress the problem of the reduced space between the fourth wiring portions 44, leading to suppression of a short-circuit defect.

Furthermore, in the present embodiment, as described above, the structures of FIGS. 2A, 2B, and 2C are formed from roughly two steps. Regarding the contact wiring 40, the wiring portions 41 and 43 on the lower layer side are formed in the first step, and the wiring portions 42 and 44 on the upper layer side are formed in the second step. This makes it possible to properly form the contact wiring 40.

For example, comparing the contact wiring 40a and the contact wiring 40d illustrated in FIG. 2B, the overall height of the contact wiring 40a is significantly different from the overall height of the contact wiring 40d. Therefore, forming the contact wiring 40a and the contact wiring 40d in a single common process would lead to a possibility of occurrence of large variation between the structures.

Forming the contact wiring 40a in one step would lead to a structure in which the wiring portions 41a, 42a and 43a of the contact wiring 40a are linearly extended in the vertical direction (Z-direction). Therefore, it is necessary to deepen the hole for forming the contact wiring 40a, and consequently the depth of the hole for forming the contact wiring 40a would greatly differ from the depth of the hole for forming the contact wiring 40d. These holes are usually formed by reactive ion etching (RIE), and forming a plurality of holes having greatly different depths in a common RIE process would not be easy. For example, when the hole for the contact wiring 40a is formed up to the position of the connection portion C1, there would be a problem that the hole for the contact wiring 40d penetrates through the conductive layer 21b and the insulating layer 22b of the connection portion C2 to reach the conductive layer 21b located on the lower layer side of the connection portion C2.

In the present embodiment, the contact wiring 40 is formed in a two-step process, that is, the hole for the contact wiring 40 is formed in a two-step process. This makes it possible to reduce the difference in the depth of the holes formed in one common step, leading to prevention of the problem described above.

Note that the pillar portion 30a, the pillar portion 30b, and the intermediate portion 30c may be integrally formed for each of the plurality of pillar structures 30 provided with a same height. For example, the hole for forming the pillar portion 30a and the intermediate portion 30c is processed in a first step, and the hole for forming the pillar portion 30b is processed in a second step. The holes formed in the stacked portion 20a and the intermediate portion 20c of the stacked layer body 20 in the first step are filled with a sacrificial film before the second step. Thereafter, in the second step, the sacrificial film filled in the hole on the lower layer side is removed through the hole for forming the pillar portion 30b. Furthermore, by forming the pillar portion 30a, the pillar portion 30b, and the intermediate portion 30c in the holes on the lower layer side and the upper layer side, it is possible to form the integrated pillar structure 30.

Furthermore, while the above-described embodiment is an example in which the stacked layer body 20 includes two stacked portions (first stacked portion 20a and second stacked portion 20b), the stacked layer body 20 may include three or more stacked portions. In this case, it is also possible to form the contact wiring 40 similarly to the manner in the above-described embodiment. For example, in a case where the third stacked portion located on the upper layer side of the second stacked portion 20b is provided, it is satisfactory to provide a wiring portion connected to the wiring portion 44 of the contact wiring 40 and extending in the vertical direction (Z-direction) and provide a wiring portion connected to this wiring portion and extending parallel to the X-Y plane.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked layer body including a first stacked portion including a plurality of first conductive layers and a plurality of first insulating layers which are alternately stacked in a first direction and having a stair-like first end, and including a second stacked portion provided on an upper layer side of the first stacked portion, including a plurality of second conductive layers and a plurality of second insulating layers which are alternately stacked in the first direction and having a stair-like second end;
a plurality of pillar structures each of which extending in the first direction within the stacked layer body and each of which including a semiconductor layer extending in the first direction and a charge storage layer surrounding a side surface of the semiconductor layer;
an insulating region adjacent to the first and second ends of the stacked layer body, the insulating region including a first insulating region portion covering the first end of the stacked layer body and including a second insulating region portion provided on an upper layer side of the first insulating region portion and covering the second end of the stacked layer body; and
a plurality of first contact wirings each of which including a first wiring portion that is connected to a portion located at the first end of the corresponding first conductive layer and extends in the first direction within the first insulating region portion, a second wiring portion extending in the first direction within the second insulating region portion, and a third wiring portion connected between an upper end of the first wiring portion and a lower end of the second wiring portion,
wherein a pattern of the first wiring portion and a pattern of the second wiring portion included in one of the first contact wirings are arranged at positions different from each other when viewed in the first direction.

2. The device according to claim 1,
wherein each of the first contact wirings further includes a fourth wiring portion connected to an upper end of the second wiring portion, and
the fourth wiring portion included in the one of the first contact wirings extends from a portion connected to the upper end of the second wiring portion included in the one of the first contact wirings, in parallel to a plane perpendicular to the first direction.

3. The device according to claim 1,
wherein a pattern of the first wiring portion, a pattern of the second wiring portion, and a pattern of the third wiring portion which are included in another one of the first contact wirings are arranged at positions corresponding to each other when viewed in the first direction.

4. The device according to claim 1,
wherein the stacked layer body further includes an intermediate portion located between the first stacked portion and the second stacked portion.

5. The device according to claim 4,
wherein a position of the third wiring portion included in the one of the first contact wirings in the first direction corresponds to a position of the intermediate portion of the stacked layer body in the first direction.

6. The device according to claim 1,
further comprising a plurality of second contact wirings,
wherein each of the second contact wirings includes:
a fifth wiring portion connected to a portion located at the second end of the corresponding second conductive layer and extending in the first direction within the second insulating region portion; and
a sixth wiring portion connected to an upper end of the fifth wiring portion, and
the sixth wiring portion included in one of the second contact wirings extends from the portion connected to the upper end of the fifth wiring portion included in the one of the second contact wirings, in parallel to a plane perpendicular to the first direction.

7. The device according to claim 6,
wherein a position of an upper surface of the fifth wiring portion included in the one of the second contact wirings in the first direction corresponds to a position of an upper surface of the second wiring portion included in the one of the first contact wirings in the first direction.

8. The device according to claim 1,
wherein the third wiring portion included in the one of the first contact wirings includes: a first end portion including a portion connected to the first wiring portion included in the one of the first contact wirings; a second end portion including a portion connected to the second wiring portion included in the one of the first contact wirings; and an extension portion that extends between the first end portion and the second end portion in parallel to a plane perpendicular to the first direction.

9. The device according to claim 8,
wherein the extension portion is provided linearly.

10. The device according to claim 8,
wherein the extension portion is bent at one or more positions.

11. The device according to claim 8,
wherein a pattern of the first end portion includes the pattern of the first wiring portion included in the one of the first contact wirings thereinside when viewed in the first direction.

12. The device according to claim 8,
wherein a pattern of the second end portion includes the pattern of the second wiring portion included in the one of the first contact wirings thereinside when viewed in the first direction.

13. The device according to claim 1,
wherein each of the pillar structures includes: a first pillar portion extending in the first direction within the first stacked portion, a second pillar portion located above the first pillar portion and extending in the first direction within the second stacked portion; and an intermediate portion located between the first pillar portion and the second pillar portion.

14. The device according to claim 13,
wherein a position of the third wiring portion included in the one of the first contact wirings in the first direction corresponds to a position of the intermediate portion of each of the pillar structures in the first direction.

15. The device according to claim 13,
wherein one of the first conductive layers together with a first portion of the first pillar portion included in one of the pillar structures, the first portion being surrounded by the one of the first conductive layers, form one memory cell of NAND type nonvolatile memory, and
one of the second conductive layers together with a second portion of the second pillar portion included in the one of the pillar structures, the second portion being surrounded by the one of the second conductive layers, form another memory cell of the NAND type nonvolatile memory.

16. The device according to claim 13,
wherein each of the pillar structures has the first pillar portion, the second pillar portion, and the intermediate portion being integrated with each other.

17. The device according to claim 13,
wherein an area of a pattern of the intermediate portion is larger than an area of a pattern of the first pillar portion and an area of a pattern of the second pillar portion in each of the pillar structures when viewed in the first direction.

18. The device according to claim 1,
wherein each of the pillar structures further includes a tunnel insulating layer provided between the semiconductor layer and the charge storage layer.

19. The device according to claim 1, further comprising:
a MOS transistor covered with the insulating region; and
a third contact wiring including a seventh wiring portion connected to the MOS transistor and extending within the first insulating region portion in the first direction, an eighth wiring portion extending within the second insulating region portion in the first direction, and a ninth wiring portion connected between an upper end of the seventh wiring portion and a lower end of the eighth wiring portion.

20. The device according to claim 19,
wherein a pattern of the seventh wiring portion and a pattern of the eighth wiring portion are arranged at positions different from each other when viewed in the first direction.
